(19) United States
(12) Patent Application Publication
(10) Pub. No.: US 2021/0021266 A1
(43) Pub. Date: Jan. 21, 2021

(54) SEMICONDUCTOR INTEGRATED CIRCUIT WITH RADIATION RESISTANCE

(71) Applicants: Kabushiki Kaisha Toshiba, Tokyo (JP); Toshiba Electronic Devices & Storage Corporation, Tokyo (JP)

(72) Inventors: Youichi Satou, Kawasaki Kanagawa (JP); Masazumi Shiochi, Fuchu Tokyo (JP)

(21) Appl. No.: 16/787,675

(22) Filed: Feb. 11, 2020

(30) Foreign Application Priority Data
Jul. 18, 2019 (JP) 2019-132866

(51) Int. Cl. H03K 19/003; H01L 29/423; H01L 27/092; H01L 29/08; H01L 27/12; H01L 29/51

(52) U.S. Cl. CPC H03K 19/00338; H01L 29/42376; H01L 27/092; H01L 29/518; H01L 27/1207; H01L 29/513; H01L 29/0847

(57) ABSTRACT

According to an embodiment, a semiconductor integrated circuit includes a signal processing circuit with a first transistor and a second transistor connected in series, and a third transistor. The signal processing circuit is supplied with power from a power source, and receives a first input signal at control terminals of the first transistor and the second transistor, and execute signal processing based on the first input signal to output an output signal. The third transistor is provided between the signal processing circuit and a ground potential and receives a second input signal at a control terminal of the third transistor, the second input signal obtained by level-shifting the first input signal and thereby having a smaller signal amplitude than a signal amplitude of the first input signal, and be turned on or off based on the second input signal.

### CROSS REFERENCE TO RELATED APPLICATION

This application is based upon and claims the benefit of priority from the prior Japanese Patent Application No. 2019-132866, filed on Jul. 18, 2019, the entire contents of which are incorporated herein by reference.

The embodiments described herein relate to a semiconductor integrated circuit with radiation resistance.

Semiconductor integrated circuits have been mounted on machines in many fields including industrial machines and consumer machines and used in various environments. Recently, the semiconductor integrated circuits have been used also in severe environments where the semiconductor integrated circuits are exposed to radiation such as electron beams, X-rays, γ-rays, and α-rays.

Irradiation of a semiconductor integrated circuit with the radiation causes degradation or destruction of elements included in the semiconductor integrated circuit, erroneous operation of the circuit, and the like. The irradiation with the radiation causes an increase of a leak current of a MOS transistor, degradation or destruction of a gate insulator film of the MOS transistor, and the like, for example. In addition, in an active region and a substrate surface where the MOS transistor is formed, holes and electrons are generated to cause a transient current to flow in the circuit, and thus the circuit erroneously operates.

For this reason, a semiconductor integrated circuit with radiation resistance has been demanded strongly for machines such as a machine generating radiation and a machine for the outer space.

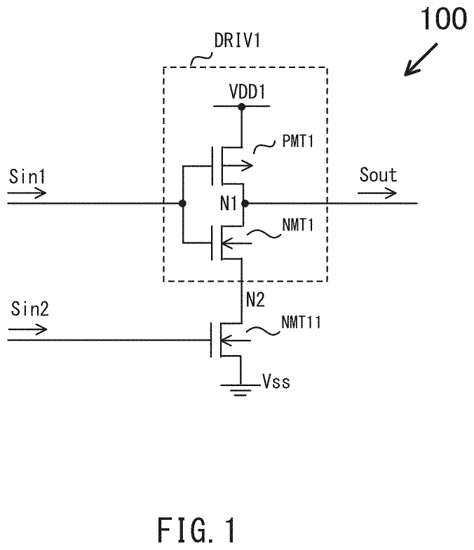

FIG. 1 is a circuit diagram showing a semiconductor integrated circuit according to a first embodiment;

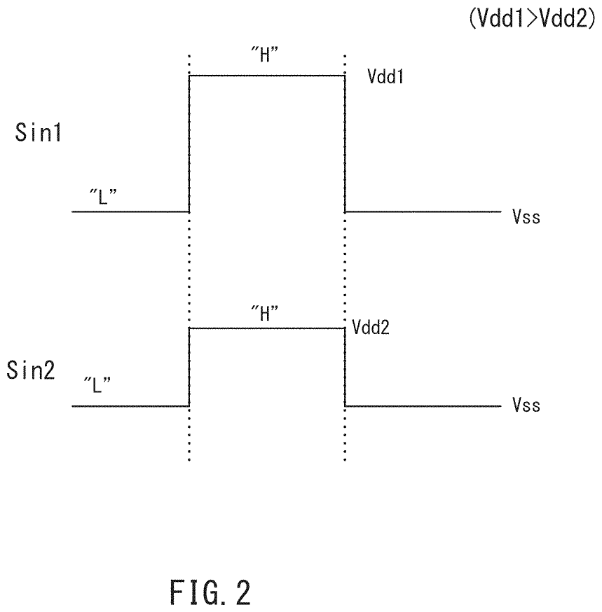

FIG. 2 is an explanatory diagram of input signal waves according to the first embodiment;

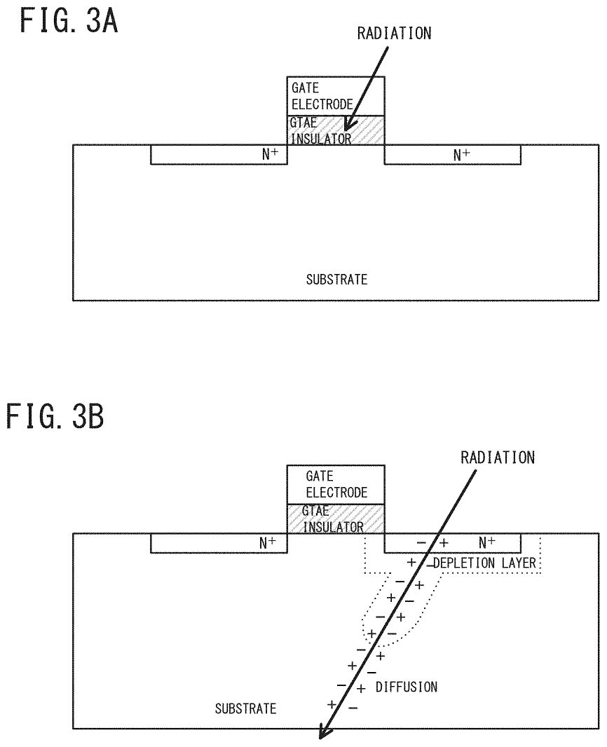

FIG. 3A is an explanatory diagram of radiation irradiating a gate of a MOS transistor;

FIG. 3B is an explanatory diagram of radiation irradiating a source region or a drain region of the MOS transistor;

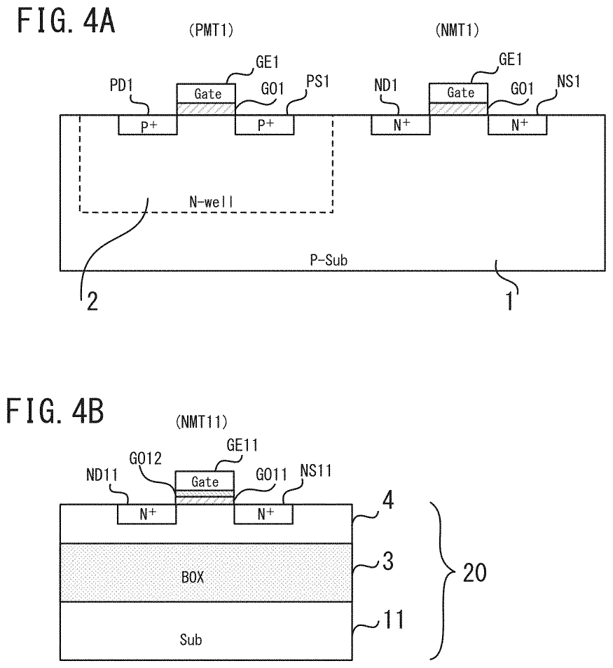

FIG. 4A is a cross-sectional view of MOS transistors included in a driver circuit according to the first embodiment;

FIG. 4B is a cross-sectional view of a MOS transistor provided between the driver circuit and a ground potential according to the first embodiment;

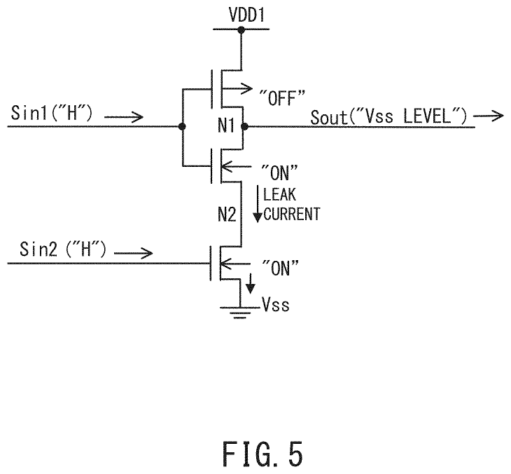

FIG. 5 is an explanatory diagram of operations of the semiconductor integrated circuit according to the first embodiment;

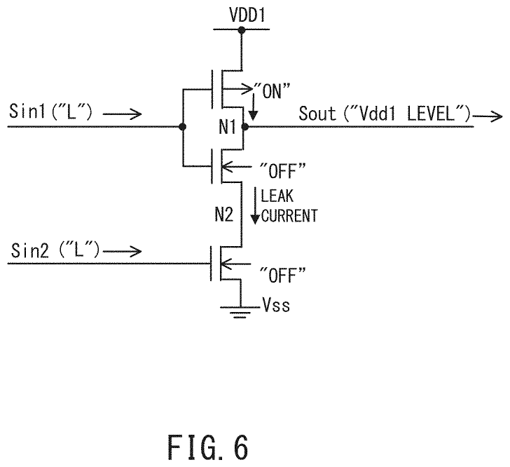

FIG. 6 is an explanatory diagram of operations of the semiconductor integrated circuit according to the first embodiment;

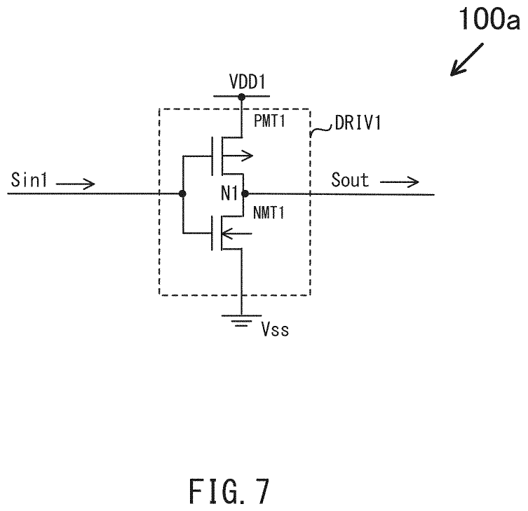

FIG. 7 is a circuit diagram showing a semiconductor integrated circuit of a first comparative example;

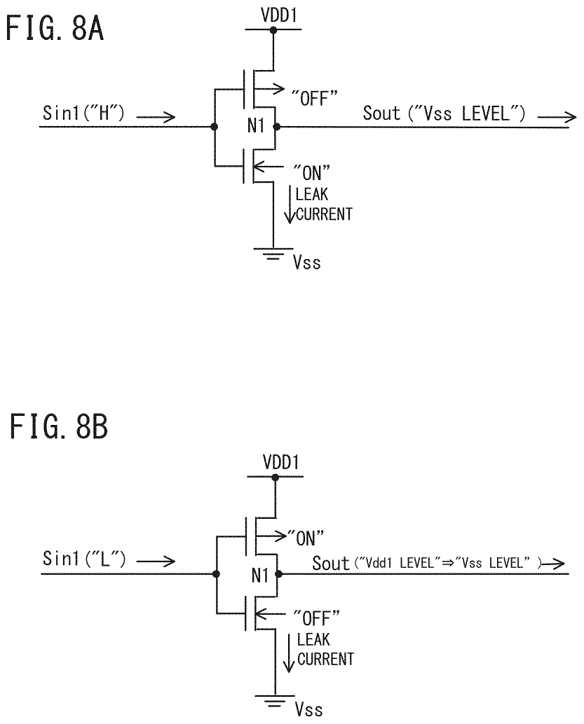

FIG. 8A is an explanatory diagram of operations of the semiconductor integrated circuit of the first comparative example;

FIG. 8B is an explanatory diagram of operations of the semiconductor integrated circuit of the first comparative example;

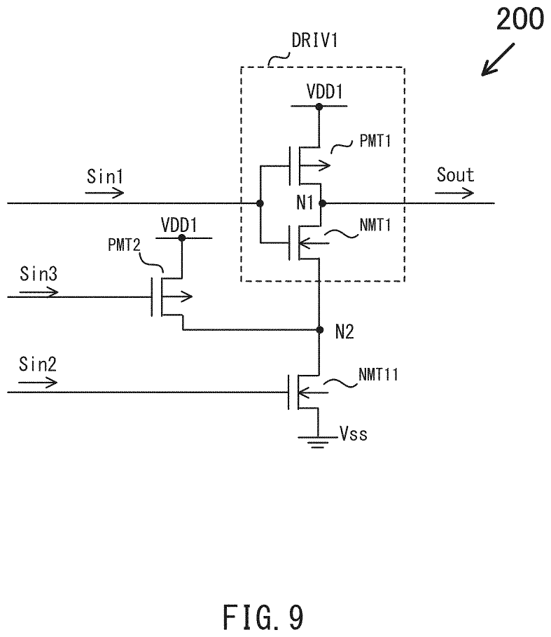

FIG. 9 is a circuit diagram showing a semiconductor integrated circuit according to a second embodiment;

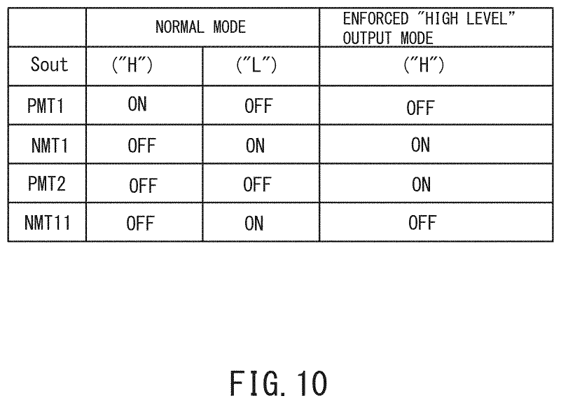

FIG. 10 is an explanatory diagram of an enforced “H” output mode of the semiconductor integrated circuit according to the second embodiment;

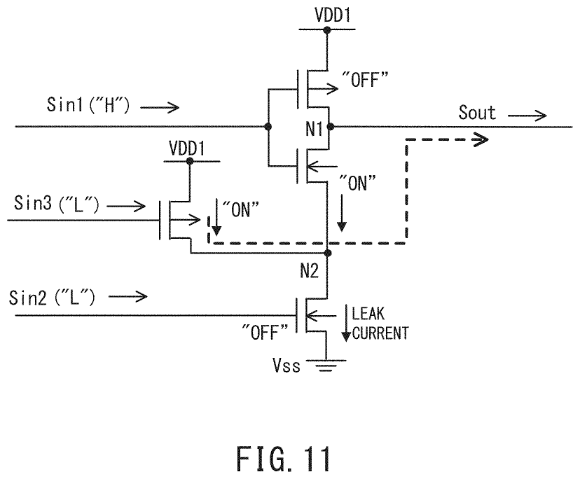

FIG. 11 is an explanatory diagram of operations in the enforced “H” output mode of the semiconductor integrated circuit according to the second embodiment;

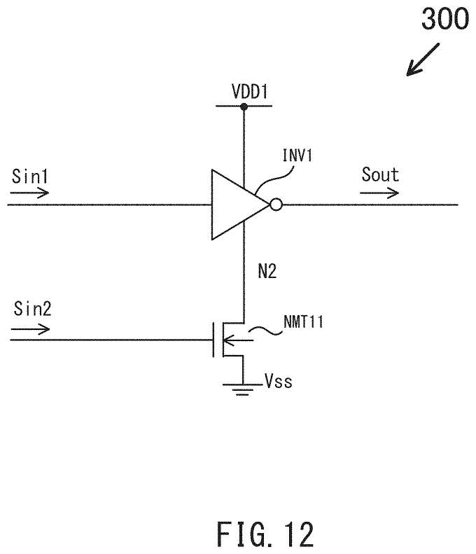

FIG. 12 is a circuit diagram showing a semiconductor integrated circuit according to a third embodiment;

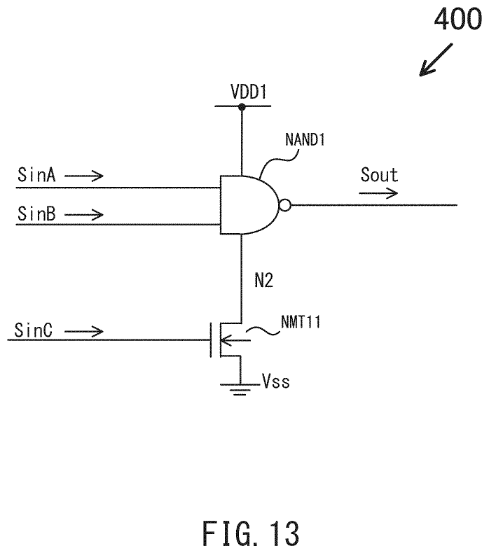

FIG. 13 is a circuit diagram showing a semiconductor integrated circuit according to a fourth embodiment;

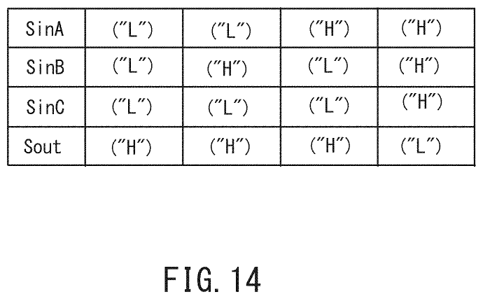

FIG. 14 is an explanatory diagram of signal levels in the semiconductor integrated circuit according to the fourth embodiment;

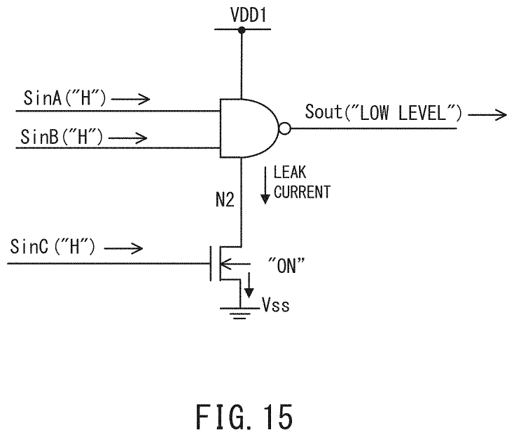

FIG. 15 is an explanatory diagram of operations of the semiconductor integrated circuit according to the fourth embodiment;

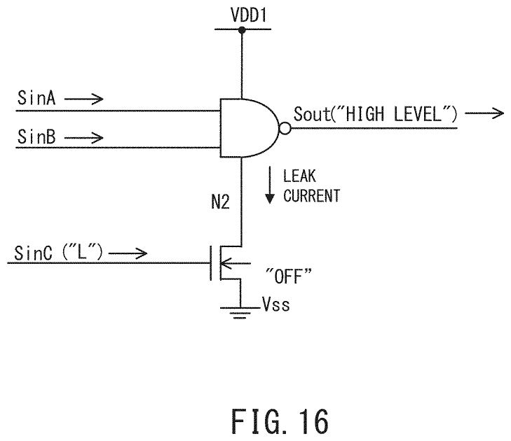

FIG. 16 is an explanatory diagram of operations of the semiconductor integrated circuit according to the fourth embodiment;

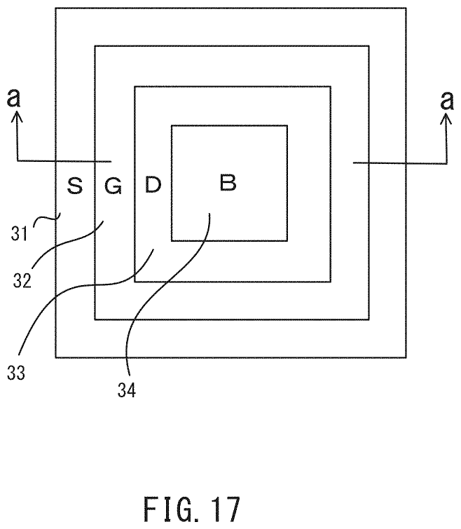

FIG. 17 is a plan view showing a ring-gate MOS transistor of a first modification;

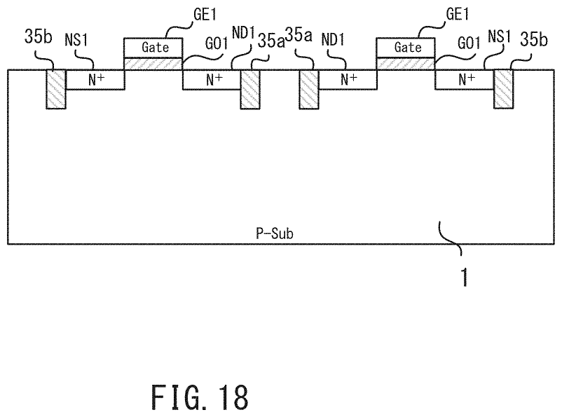

FIG. 18 is a cross-sectional view showing the ring-gate MOS transistor of the first modification taken along the a-a line in FIG. 17;

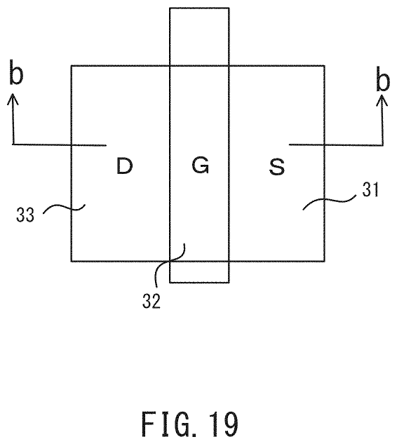

FIG. 19 is a plan view showing a rectangular MOS transistor of a second comparative example;

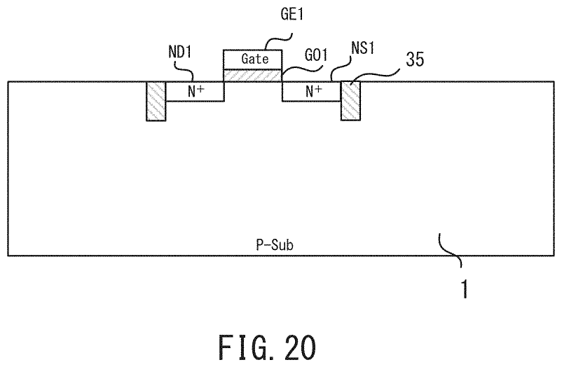

FIG. 20 is a cross-sectional view showing the rectangular MOS transistor of the second comparative example taken along the b-b line in FIG. 19; and

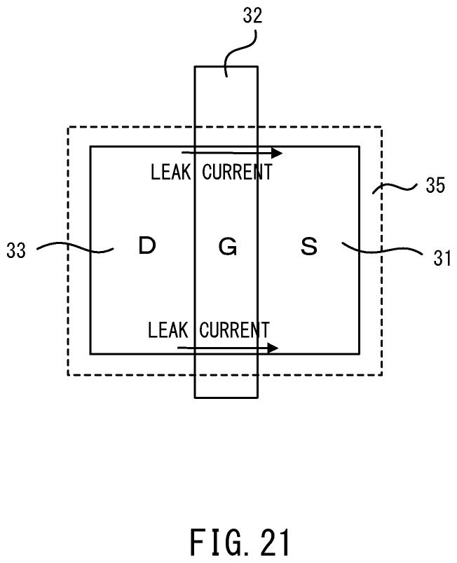

FIG. 21 is an explanatory diagram of flows of leak currents generated in the rectangular MOS transistor of the second comparative example.

According to an embodiment, a semiconductor integrated circuit includes a signal processing circuit with a first transistor and a second transistor connected in series, and a third transistor. The signal processing circuit is supplied with power from a power source, and receives a first input signal at control terminals of the first transistor and the second transistor, and executes signal processing based on the first input signal to output an output signal. The third transistor is provided between the signal processing circuit and a ground potential and receives a second input signal at a control terminal of the third transistor, the second input signal obtained by level-shifting the first input signal and thereby having a smaller signal amplitude than a signal amplitude of the first input signal, and be turned on or off based on the second input signal.

In addition, a plurality of embodiments are described below with reference to the drawings. In the drawings, the same reference signs represent the same or similar portions.

A semiconductor integrated circuit according to a first embodiment will be described with reference to the drawings. FIG. 1 is a circuit diagram showing the semiconductor integrated circuit.

In the first embodiment, a transistor with the higher radiation resistance than the radiation resistance of transistors included in a driver circuit is provided between the driver circuit and a ground potential, and the normal operation of the semiconductor integrated circuit is maintained even when the properties of the transistors included in the driver circuit are degraded due to the radiation.

As shown in FIG. 1, a semiconductor integrated circuit 100 includes a driver circuit DRIV1 and a MOS transistor NMT11. The semiconductor integrated circuit 100 is a semiconductor integrated circuit with radiation resistance, which is mounted in a machine generating electron beams and a machine for the outer space. The semiconductor integrated circuit 100 is mounted in an electron-beam lithography device, for example.

The driver circuit DRIV1 includes a MOS transistor PMT1 and a MOS transistor NMT1. A MOS transistor is also referred to as a MOSFET.

The driver circuit DRIV1 is a signal processing circuit to which an input signal Sin1 is inputted, and the driver circuit DRIV1 executes signal processing based on the input signal Sin1 and outputs an output signal Sout. The output signal Sout is a driven current signal.

The MOS transistor PMT1 is a P-channel MOS transistor. In the MOS transistor PMT1, one end (source) is connected to a power source VDD1 (high potential side power source), the other end (drain) is connected to a node N1, and the input signal Sin1 is inputted to a gate (control terminal).

The MOS transistor NMT1 is an N-channel MOS transistor. In the MOS transistor NMT1, one end (drain) is connected to the node N1 (the other end of the MOS transistor PMT1), the other end (source) is connected to a node N2, and the input signal Sin1 is inputted to a control terminal (gate).

The MOS transistor NMT11 is an N-channel MOS transistor. The MOS transistor NMT11 is provided between the driver circuit DRIV1 and a ground potential Vss (low potential side power source). In the MOS transistor NMT11, one end (drain) is connected to the node N2 (the other end of the MOS transistor NMT1), the other end (source) is connected to the ground potential Vss (low potential side power source), an input signal Sin2 is inputted to a control terminal (gate), and operation of the MOS transistor NMT11 is turned on or off based on the input signal Sin2.

The input signal Sin1 and the input signal Sin2 will be described with reference to FIG. 2. FIG. 2 is an explanatory diagram of input signal waves.

As shown in FIG. 2, the input signal Sin1 is a signal in which the high level (“H” level) is a voltage Vdd1, and the low level (“L” level) is the ground potential Vss (low potential side power source). The input signal Sin2 is a signal in which the high level (“H” level) is a voltage Vdd2, and the low level (“L” level) is the ground potential Vss (low potential side power source). The input signal Sin2 is a signal that is generated by shifting the level of the input signal Sin1 by using a not-shown level-shift circuit, for example, and the input signal Sin2 has the same signal variation as that of the input signal Sin1. The relationship between the voltage Vdd1 and the voltage Vdd2 is set to be Vdd1>Vdd2. Specifically, the relationship is set to be Vdd2=Vdd1×(½), for example.

It is preferred to set an absolute value of a threshold voltage of the MOS transistor NMT11 smaller than absolute values of threshold voltages of the MOS transistor PMT1 and the MOS transistor NMT1.

The case where radiation enters the MOS transistor will be described with reference to FIGS. 3A and 3B. FIG. 3A is an explanatory diagram of radiation irradiating the gate of the MOS transistor. FIG. 3B is an explanatory diagram of radiation irradiating the source region or the drain region of the MOS transistor.

As shown in FIG. 3A, when the radiation irradiates a gate insulator film through a gate electrode, degradation or breakdown of the gate insulator film occurs. Once the degradation or breakdown of the gate insulator film occurs, the insulation between the gate electrode and the source, the drain, or the substrate is considerably reduced, and leak currents between the gate and the source, between the gate and the drain, between the source and the drain, between the gate and the substrate, and the like are increased.

As shown in FIG. 3B, once the substrate is irradiated with the radiation through a diffusion layer (source or drain), holes and electrons are generated along the beam path of the radiation. The holes and the electrons are diffused, a depletion layer extends directly below the diffusion layer, an excessive current is generated, and erroneous operation of the semiconductor integrated circuit is induced. The irradiation with the radiation causes also the degradation of a junction layer (PN junction), and an inverse direction leak current is increased.

In the first embodiment, a MOS transistor with radiation resistance is provided in the semiconductor integrated circuit 100. The MOS transistor with radiation resistance will be described with reference to FIGS. 4A and 4B. FIG. 4A is a cross-sectional view of the MOS transistors included in the driver circuit. FIG. 4B is a cross-sectional view of the MOS transistor provided between the driver circuit and the ground potential.

As shown in FIG. 4A, the MOS transistor PMT1 and the MOS transistor NMT1 are formed on a substrate 1 (P-type silicon substrate). In the MOS transistor PMT1, a source layer PS1 and a drain layer PD1 are formed on a surface of an N-well layer 2. A gate electrode GE1 is formed between the source layer PS1 and the drain layer PD1 on the N-well layer 2, with a gate insulator film GO1 arranged between the gate electrode GE1 and the N-well layer 2.

In the MOS transistor NMT1, a source layer NS1 and a drain layer ND1 are formed on the surface of the substrate 1. The gate electrode GE1 is formed between the source layer NS1 and the drain layer ND1 on the substrate 1, with the gate insulator film GO1 arranged between the gate electrode GE1 and the substrate 1.

The gate insulator film GO1 is a silicon oxide film (SiO₂ film), which is a silicon thermally oxidized film formed at high temperature, for example.

As shown in FIG. 4B, the MOS transistor NMT11 is formed on an SOI (Silicon on Insulator) substrate 20. The SOI substrate 20 is formed by layering a substrate 11, a buried oxidized film (BOX) layer 3, and a body layer 4 (P-type body layer). The thickness of the body layer 4 is significantly thinner than the thickness of the substrate 1.

In the MOS transistor NMT11, a source layer NS11 and a drain layer ND11 are formed on a surface of the body layer 4. Agate electrode GE11 is formed between the source layer NS11 and the drain layer ND11 on the body layer 4, with a gate insulator film GO11 and a gate insulator film GO12 (composite film) arranged between the gate electrode GE11 and the body layer 4.

The depth of diffusion layers of the source layer NS11 and the drain layer ND11 are shallower than the depth of diffusion layers of the source layer PS1, the drain layer PD1, the source layer NS1, and the drain layer ND1.

The gate insulator film GO11 is a silicon oxide film (SiO₂ film), for example, and the gate insulator film GO12 is a silicon nitride film (SiN film), for example.

Although the composite film including a silicon oxide film (SiO₂ film) and a silicon nitride film (SiN film) is used in the embodiment, the embodiment is not necessarily limited to the above case. For example, a composite film including a silicon oxide film (SiO₂ film) and a silicon oxynitride film (SiON film), a composite film including a silicon oxide film (SiO₂ film), a silicon oxynitride film (SiON film), and a silicon nitride film (SiN film), and so on may be used.

Since the MOS transistor NMT11 uses the composite film including a silicon oxide film (SiO₂ film) and a silicon nitride film (SiN film) as the gate insulator film, it is possible to suppress the degradation or the breakdown of the gate insulator film due to the irradiation with the radiation more than in the case of using the MOS transistor PMT1 and the MOS transistor NMT1.

Since the thickness of the body layer 4 is made significantly thinner than the thickness of the substrate 1, and the depth of the diffusion layer is made shallow, it is possible to reduce the amounts of the holes and the electrons generated by the irradiation with the radiation, considerably reduce the excessive current, and suppress the erroneous operation of the circuit. Additionally, the degradation of the junction layer (PN junction) can be also suppressed.

Thus, the MOS transistor NMT11 functions as a transistor with higher radiation resistance than the radiation resistance of the MOS transistor PMT1 and the MOS transistor NMT1.

Next, operations of the integrated circuit will be described with reference to FIGS. 5 and 6. FIG. 5 is an explanatory diagram of operations of the semiconductor integrated circuit when the input signal Sin1 and the input signal Sin2 are at the high level. FIG. 6 is an explanatory diagram of operations of the semiconductor integrated circuit when the input signal Sin1 and the input signal Sin2 are at the low level.

In this case, the leak currents in the MOS transistor PMT1 and the MOS transistor NMT1 are increased due to the irradiation with the radiation, but the MOS transistor NMT11 operates normally with no degradation of the property occurs due to the irradiation with the radiation.

As shown in FIG. 5, the MOS transistor PMT1 is turned off when the input signal Sin1 at the high level (“H” level) is inputted to the gate. The MOS transistor NMT1 is turned on when the input signal Sin1 at the high level (“H” level) is inputted to the gate. The MOS transistor NMT11 is turned on when the input signal Sin2 at the high level (“H” level) is inputted to the gate.

Consequently, an on-current and the leak current flow from the source side of the MOS transistor NMT1 to the ground potential side Vss (low potential side power source) of the MOS transistor NMT1, and the output signal Sout is shifted to be at the low level (“Vss level”).

As shown in FIG. 6, the MOS transistor PMT1 is turned on when the input signal Sin1 at the low level (“L” level) is inputted to the gate. The MOS transistor NMT1 is turned off when the input signal Sin1 at the low level (“L” level) is inputted to the gate. The MOS transistor NMT11 is turned off when the input signal Sin2 at the low level (“L” level) is inputted to the gate.

Since the MOS transistor NMT11 operates normally, the MOS transistor NMT11 interrupts the leak current flowing from the MOS transistor NMT1. Consequently, it is possible to maintain the output signal Sout at the high level (“Vdd1 level”).

Next, a semiconductor integrated circuit of a comparative example will be described with reference to FIG. 7. FIG. 7 is a circuit diagram showing the semiconductor integrated circuit of the comparative example.

As shown in FIG. 7, a semiconductor integrated circuit 100a of the first comparative example is provided with a drive circuit DRIV1 but not provided with the MOS transistor NMT11 of the first embodiment 100.

Operations of the semiconductor integrated circuit 100a of the comparative example of the case where the properties of the MOS transistor PMT1 and the MOS transistor NMT1 included in the drive circuit DRIV1 are degraded due to the irradiation with the radiation will be described with reference to FIGS. 8A and 8B. FIG. 8A is an explanatory diagram of operations of the semiconductor integrated circuit of the first comparative example when the input signal Sin1 is at the high level. FIG. 8B is an explanatory diagram of operations of the semiconductor integrated circuit of the first comparative example when the input signal Sin1 is at the low level.

As shown in FIG. 8A, the MOS transistor PMT1 is turned off when the input signal Sin1 at the high level (“H” level) is inputted to the gate. The MOS transistor NMT1 is turned on when the input signal Sin1 at the high level (“H” level) is inputted to the gate.

Consequently, the on-current and the leak current flow from the source side of the MOS transistor NMT1 to the ground potential side Vss (low potential side power source), and the output signal Sout is shifted to be at the low level (“Vss level”).

As shown in FIG. 8B, the MOS transistor PMT1 is turned on when the input signal Sin1 at the low level (“L” level) is inputted to the gate. The MOS transistor NMT1 is turned off when the input signal Sin1 at the low level (“L” level) is inputted to the gate. Since the leak currents are generated in the MOS transistor PMT1 and the MOS transistor NMT1, the leak currents flow from the source side of the MOS transistor NMT1 to the ground potential side Vss (low potential side power source).

Consequently, the output signal Sout cannot be maintained at the high level (“Vdd1 level”) and is shifted to be at the low level (“Vss level”), and this causes the erroneous operation.

Although an SOI-type MOS transistor is used as the MOS transistor NMT11 in the first embodiment, a ring-gate MOS transistor may be used instead to suppress the generation of the leak currents like a first modification. The detail of the first modification will be described below with reference to FIGS. 17 to 21.

FIG. 17 is a plan view showing the ring-gate MOS transistor of the first modification. FIG. 18 is a cross-sectional view showing the ring-gate MOS transistor of the first modification taken along the a-a line in FIG. 17. FIG. 19 is a plan view showing a rectangular MOS transistor of a second comparative example. FIG. 20 is a cross-sectional view showing the rectangular MOS transistor of the second comparative example taken along the b-b line in FIG. 19. FIG. 21 is an explanatory diagram of flows of leak currents generated in the rectangular MOS transistor of the second comparative example.

As shown in FIG. 17, in the first modification, the ring-gate MOS transistor is used as the MOS transistor NMT11. In the ring-gate MOS transistor, a body 34 (substrate) is provided inside of the ring-gate MOS transistor, a drain 33 is provided outside the body 34, a gate 32 is provided outside the drain 33, and a source 31 is provided outside the gate 32. In the ring-gate MOS transistor, the source 31 is formed away from the drain 33 with the gate 32 arranged between the source 31 and the drain 33.

Although the body 34 is in a rectangular-shape, and the drain 33, the gate 32, and the source 31 are in a ring-gate-shape having four corners in the embodiment, the embodiment is not necessarily limited to the above case. Instead, the body 34, the drain 33, the gate 32, and the source 31 may be in a circular-shape or an oval-shape.

As shown in FIG. 18, a shallow trench isolation (STI) 35a (first STI) is provided on the inner peripheral side of the drain layer ND1 arranged opposite. A shallow trench isolation (STI) 35b (second STI) is provided on the outer peripheral side of the source layer NS1 arranged opposite. The STIs 35a, 35b are formed deeper than the drain layer ND1 and the source layer NS1.

The ring-gate MOS transistor is an edgeless transistor in which edges of the gate 32 do not come in contact with the source 31 and the drain 33.

In contrast, in the second comparative example, a rectangular MOS transistor is used as the MOS transistor NMT11.

As shown in FIG. 19, in the rectangular MOS transistor, the source 31 and the drain 33 are in rectangular-shape, and an SDG region including the source, the drain, and the gate is in rectangular-shape. As shown in FIG. 20, an STI 35 is provided to an end portion of the source layer NS1, the end portion being opposite the gate insulator film GO1 and the gate electrode GE1. The STI 35 is provided to an end portion of the drain layer ND1, the end portion being opposite the gate insulator film GO1 and the gate electrode GE1. The STI 35 is formed deeper than the drain layer ND1 and the source layer NS1.

When the ring-gate MOS transistor is irradiated with the radiation, since the source 31 is formed away from the drain 33 with the gate 32 arranged between the source 31 and the drain 33 in the ring-gate MOS transistor, it is possible to suppress the leak currents at the boundary of the STI 35. Consequently, it is possible to determine that the ring-gate MOS transistor has the radiation resistance.

In contrast, as shown in FIG. 21, when the rectangular MOS transistor is irradiated with the radiation, the leak currents generated at the boundary of the STI 35 flow from the drain in a direction toward the source in the rectangular MOS transistor. Consequently, it is possible to determine that the radiation resistance property of the rectangular MOS transistor is lower than the radiation resistance property of the ring-gate MOS transistor.

Although the ring-gate MOS transistor is used as the MOS transistor NMT11 in the first modification, the embodiment is not necessarily limited to the above case. For example, the ring-gate MOS transistor may also be used as the MOS transistor NMT1 included in the driver circuit DRIV1.

As described above, the semiconductor integrated circuit 100 of the embodiment is provided with the driver circuit DRIV1 and the MOS transistor NMT11. The driver circuit DRIV1 includes the MOS transistor PMT1 and the MOS transistor NMT1. The MOS transistor NMT11 is formed on the SOI substrate 20, and the gate insulator film is the composite film including the gate insulator film GO11 and the gate insulator film GO12. The MOS transistor PMT1 and the MOS transistor NMT1 are formed on the substrate 1 (P-type silicon substrate), and the gate insulator film GO1 is a silicon oxide film. The MOS transistor NMT11 is a transistor with the higher radiation resistance than the radiation resistance of the MOS transistor PMT1 and the MOS transistor NMT1.

This allows the MOS transistor NMT11 to operate normally even when the properties of the MOS transistor PMT1 and the MOS transistor NMT1 are degraded due to the radiation and the leak currents are increased, and thus it is possible to prevent the erroneous operation of the semiconductor integrated circuit 100.

Although the MOS transistor PMT1 and the MOS transistor NMT1 are formed on the substrate 1 (P-type silicon substrate) and the MOS transistor NMT11 is formed on the SOI substrate 20 in the first embodiment, the embodiment is not necessarily limited to the above case. For example, the MOS transistor PMT1 and the MOS transistor NMT1 may be formed on a partial depletion-type SOI substrate, and the MOS transistor NMT11 may be formed on a complete depletion-type SOI substrate including a thin body layer.

The MOS transistor PMT1, the MOS transistor NMT1, and the MOS transistor NMT11 may be formed on a partial SOI substrate. In this case, it is preferred to form the MOS transistor PMT1 and the MOS transistor NMT1 on a silicon substrate portion and form the MOS transistor NMT11 on an SOI substrate portion.

A semiconductor integrated circuit according to a second embodiment will be described with reference to the drawings. FIG. 9 is a circuit diagram showing the semiconductor integrated circuit.

In the second embodiment, the third transistor, which has the higher radiation resistance than the radiation resistance of the first and second transistors included in the driver circuit, is provided between the driver circuit and the ground potential, and a fourth transistor is provided between the power source and the low potential side of the driver circuit. The fourth transistor sets an enforced high level output mode, and it is possible to maintain the normal operation of the semiconductor integrated circuit even when the leak current is generated because of the property degradation of the first to fourth transistors due to the irradiation with the radiation.

Hereinafter, the components same as the components of the first embodiment are indicated by the same reference signs and the descriptions of the components are omitted, while only the different portions are described.

As shown in FIG. 9, a semiconductor integrated circuit 200 includes the driver circuit DRIV1, the MOS transistor NMT11, and a MOS transistor PMT2. The semiconductor integrated circuit 200 is a semiconductor integrated circuit with radiation resistance and is mounted in machines such as a machine generating electron beam and a machine for the outer space. The semiconductor integrated circuit 200 is mounted in an electron-beam lithography device, for example.

The MOS transistor PMT2 is a P-channel MOS transistor and is formed on the substrate 1 (P-type silicon substrate) as the MOS transistor PMT1 and the MOS transistor NMT1 do.

In the MOS transistor PMT2, one end (source) is connected to the power source VDD1, and the other end (drain) is connected to the node N2 (the other end of the MOS transistor NMT1 and one end of the MOS transistor NMT11), the MOS transistor PMT2 receives, at a control terminal (gate), an input of an input signal Sin3, and the MOS transistor PMT2 is turned on or off based on the input signal Sin3. The MOS transistor PMT2 sets the enforced high level output mode based on the input signal Sin3.

The input signal Sin3 is a signal in which the high level (“H” level) is the voltage Vdd1, and the low level (“L” level) is the ground potential Vss (low potential side power source).

Operations of the semiconductor integrated circuit 200 will be described with reference to FIGS. 10 and 11. FIG. 10 is an explanatory diagram of the enforced high level output mode in the semiconductor integrated circuit. FIG. 11 is an explanatory diagram of operations in the enforced high level output mode in the semiconductor integrated circuit.

As shown in FIG. 10, in a normal operation mode of the semiconductor integrated circuit 200 (when there is no property degradation due to the irradiation with the radiation), the output signal Sout is shifted to be at the high level (“Vdd1 level”) when the MOS transistor PMT1 is turned on (input signal Sin1 is at the low level), the MOS transistor NMT1 is turned off (input signal Sin1 is at the low level), the MOS transistor PMT2 is turned off (input signal Sin3 is at the high level), and the MOS transistor NMT11 is turned off (input signal Sin2 is at the low level).

The output signal Sout is shifted to be at the low level (“Vss level”) when the MOS transistor PMT1 is turned off (input signal Sin1 is at the high level), the MOS transistor NMT1 is turned on (input signal Sin1 is at the high level), the MOS transistor PMT2 is turned off (input signal Sin3 is at the high level), and the MOS transistor NMT11 is turned on (input signal Sin2 is at the high level).

When the properties of the MOS transistor PMT1, the MOS transistor NMT1, the MOS transistor NMT11, and the MOS transistor PMT2 are degraded due to the irradiation with the radiation and the leak currents are generated, the enforced high level output mode of the semiconductor integrated circuit is set.

Specifically, the output signal Sout is shifted to be at the high level (“Vdd1 level”) when the MOS transistor PMT1 is turned off (input signal Sin1 is at the high level), the MOS transistor NMT1 is turned on (input signal Sin1 is at the high level), the MOS transistor PMT2 is turned on (input signal Sin3 is at the low level), and the MOS transistor NMT11 is turned off (input signal Sin2 is at the low level).

As shown in FIG. 11, since the input signal Sin1 is set at the high level, the input signal Sin3 is set at the low level, and the input signal Sin2 is set at the low level, the on-current flowing from the MOS transistor PMT2 flows from the node N2->the MOS transistor NMT1->the output side through the node N1. The on-current is greater than the leak current flowing in the MOS transistor NMT11.

Consequently, a decrease of the output signal Sout from the high level is suppressed, and the normal operation of the semiconductor integrated circuit 200 can be maintained. When the output signal Sout is at the low level, the error operation does not occur even when the properties of the MOS transistor PMT1, the MOS transistor NMT1, the MOS transistor NMT11, and the MOS transistor PMT2 are degraded due to the irradiation with the radiation and the leak currents are generated.

As described above, the semiconductor integrated circuit 200 of the embodiment is provided with the driver circuit DRIV1, the MOS transistor NMT11, and the MOS transistor PMT2. The MOS transistor PMT2 is provided between the power source VDD1 and the node N2. In the MOS transistor PMT2, the input signal Sin3 is inputted to the gate, operation of the MOS transistor PMT2 is turned on or off based on the input signal Sin3, and the enforced high level output mode is set. When the properties of the MOS transistor PMT1, the MOS transistor NMT1, the MOS transistor NMT11, and the MOS transistor PMT2 are degraded due to the irradiation with the radiation and the leak currents are generated, a decrease of the output signal Sout from the high level is suppressed by the enforced high level output mode.

Consequently, it is possible to maintain the normal operation of the semiconductor integrated circuit 200 and prevent the erroneous operation.

Although the MOS transistor PMT2 is provided to set the enforced high level output mode in the second embodiment, the embodiment is not necessarily limited to the above case. For example, an N-channel MOS transistor may be provided instead of the MOS transistor PMT2. In this case, it is preferred to shift the input signal Sin3 to be at the high level when the enforced high level output mode is set.

A semiconductor integrated circuit according to a third embodiment will be described with reference to the drawings. FIG. 12 is a circuit diagram showing a semiconductor integrated circuit.

In the third embodiment, a transistor with higher radiation resistance than the radiation resistance of transistors included in an inverter is provided between the inverter and the ground potential, and the normal operation of the semiconductor integrated circuit is maintained even when the properties of the transistors included in the inverter are degraded due to the radiation.

Hereinafter, the components same as the components of the first embodiment are indicated by the same reference signs and the descriptions of the components are omitted, while only the different portions are described.

As shown in FIG. 12, a semiconductor integrated circuit 300 includes an inverter INV1 and the MOS transistor NMT11. The semiconductor integrated circuit 300 is a semiconductor integrated circuit with radiation resistance and is mounted in machines such as a machine generating electron beam and a machine for the outer space. The semiconductor integrated circuit 300 is mounted in an electron-beam lithography device, for example.

The inverter INV1 is provided between the power source VDD1 and the node N2, and the power source VDD1 is supplied to the inverter INV1. The inverter INV1 is a logical circuit (signal processing circuit) to which the input signal Sin1 is inputted, and the inverter INV1 executes logical operations based on the input signal Sin1 and outputs the output signal Sout.

The inverter INV1 is formed on a silicon substrate, for example. In the transistors (a P-channel MOS transistor and an N-channel MOS transistor) included in the inverter INV1, the gate insulator film is a silicon oxide film, for example. An absolute value of a threshold voltage of the MOS transistor NMT11 is set to be smaller than an absolute value of a threshold voltage of the transistors included in the inverter INV1.

As described above, the semiconductor integrated circuit 300 of the embodiment is provided with the inverter INV1 and the MOS transistor NMT11. The MOS transistor NMT11 is a transistor with higher radiation resistance than the radiation resistance of the transistors included in the inverter INV1.

Consequently, the normal operation of the semiconductor integrated circuit 300 is maintained even when the properties of the transistors included in the inverter INV1 are degraded due to the radiation, and it is possible to prevent the erroneous operation.

The MOS transistor PMT2 of the second embodiment may be added to the semiconductor integrated circuit 300 of the third embodiment to allow the semiconductor integrated circuit 300 to be set in the enforced high level output mode.

A semiconductor integrated circuit according to a fourth embodiment will be described with reference to the drawings. FIG. 13 is a circuit diagram showing the semiconductor integrated circuit.

In the fourth embodiment, a transistor with higher radiation resistance than the radiation resistance of transistors included in a two-input NAND circuit is provided between the two-input NAND circuit and the ground potential, and the normal operation of the semiconductor integrated circuit is maintained even when the properties of the transistor included in the two-input NAND circuit are degraded due to the radiation.

Hereinafter, the components same as the components of the first embodiment are indicated by the same reference signs and the descriptions of the components are omitted, while only the different portions are described.

As shown in FIG. 13, the semiconductor integrated circuit 400 includes a two-input NAND circuit NAND1 and the MOS transistor NMT11. The semiconductor integrated circuit 400 is a semiconductor integrated circuit with radiation resistance to be mounted in machines such as a machine generating electron beams and a machine for the outer space. The semiconductor integrated circuit 400 is mounted in an electron-beam lithography device, for example.

The two-input NAND circuit NAND1 is a two-input logical circuit provided between the power source VDD1 and the node N2, and the power source VDD1 is supplied to the two-input NAND circuit NAND1. The two-input NAND circuit NAND1 is a logical circuit (signal processing circuit) to which an input signal SinA and an input signal SinB are inputted, and the two-input NAND circuit NAND1 executes logical operations based on the input signal SinA and the input signal SinB and outputs the output signal Sout.

The two-input NAND circuit NAND1 is formed on a silicon substrate, for example. In the transistors (a P-channel MOS transistor and an N-channel MOS transistor) included in the two-input NAND circuit NAND1, the gate insulator film is a silicon oxide film, for example. An absolute value of a threshold voltage of the MOS transistor NMT11 is set to be smaller than an absolute value of a threshold voltage of the transistors included in the two-input NAND circuit NAND1.

The MOS transistor NMT11 is an N-channel MOS transistor. The MOS transistor NMT11 is provided between the node N2 and the ground potential Vss (low potential side power source), and an input signal SinC, which has the smaller signal amplitude than the signal amplitudes of the input signal SinA and the input signal SinB, is inputted to the gate (control terminal), and operation of the MOS transistor NMT11 is turned on or off based on the input signal SinC.

The MOS transistor NMT11 has the similar configuration as the configuration of the MOS transistor NMT11 of the first embodiment (see FIG. 4B). The MOS transistor NMT11 is a transistor with higher radiation resistance than the radiation resistance of the transistors (not shown) included in the two-input NAND circuit NAND1.

Operations of a semiconductor integrated circuit 400 will be described with reference to FIG. 14. FIG. 14 is an explanatory diagram of a signal level in the semiconductor integrated circuit.

When the properties of the transistors included in the two-input NAND circuit NAND1 and the MOS transistor NMT11 are not degraded due to the irradiation with the radiation, the semiconductor integrated circuit 400 outputs the output signal Sout at the high level when the input signal SinA is at the low level, the input signal SinB is at the low level, and the input signal SinC is at the low level (when the MOS transistor NMT11 is turned off) as shown in FIG. 14.

The semiconductor integrated circuit 400 outputs the output signal Sout at the high level when the input signal SinA is at the low level, the input signal SinB is at the high level, and the input signal SinC is at the low level (when the MOS transistor NMT11 is turned off).

The semiconductor integrated circuit 400 outputs the output signal Sout at the high level when the input signal SinA is at the high level, the input signal SinB is at the low level, and the input signal SinC is at the low level (when the MOS transistor NMT11 is turned off).

The semiconductor integrated circuit 400 outputs the output signal Sout at the low level when the input signal SinA is at the high level, the input signal SinB is at the high level, and the input signal SinC is at the high level (when the MOS transistor NMT11 is turned on).

Operations of the semiconductor integrated circuit when the property degradation of the transistors included in the two-input NAND circuit NAND1 occurs due to the irradiation with the radiation and the leak currents are increased but the property degradation of the MOS transistor NMT11 does not occur due to the irradiation with the radiation will be described with reference to FIGS. 15 and 16. FIG. 15 is an explanatory diagram of operations of the semiconductor integrated circuit when the output signal at the low level is outputted. FIG. 16 is an explanatory diagram of operations of the semiconductor integrated circuit when the output signal at the high level is outputted.

As shown in FIG. 15, when the input signal SinA at the high level and the input signal SinB at the high level are inputted to the two-input NAND circuit NAND1, the two-input NAND circuit NAND1 executes logical calculation processing and outputs the output signal Sout at the low level (“L” level). In this process, the leak current flows from the two-input NAND circuit NAND1 to the ground potential Vss (low potential side power source) side.

The input signal SinC at the high level is inputted to the gate of the MOS transistor NMT11, and the MOS transistor NMT11 is turned on. The leak current of the two-input NAND circuit NAND1 and the on-current of the MOS transistor NMT11 flow from the source side of the MOS transistor NMT11 to the ground potential Vss (low potential side power source) side, and the output signal Sout is at the low level.

As shown in FIG. 16, when the input signal SinA and the input signal SinB at the low level or the high level are inputted to the two-input NAND circuit NAND1, the two-input NAND circuit NAND1 executes logical calculation processing and outputs the output signal Sout at the high level (“H” level). In this process, the leak current flows from the two-input NAND circuit NAND1 to the ground potential Vss (low potential side power source) side.

The input signal SinC at the low level is inputted to the gate of the MOS transistor NMT11, the MOS transistor NMT11 is turned off, and the leak current flowing from the two-input NAND circuit NAND1 to the ground potential Vss (low potential side power source) side is interrupted.

Consequently, it is possible to maintain the output signal Sout at the high level and prevent the output signal Sout from shifting to the low level, and thus it is possible to maintain the normal operation of the semiconductor integrated circuit 400.

As described above, the semiconductor integrated circuit 400 of the embodiment is provided with the two-input NAND circuit NAND1 and the MOS transistor NMT11. The MOS transistor NMT11 is a transistor with the higher radiation resistance than the radiation resistance of the transistors included in the two-input NAND circuit NAND1.

Consequently, it is possible to maintain the normal operation of the semiconductor integrated circuit 400 and prevent the erroneous operation even when the properties of the transistors included in the two-input NAND circuit NAND1 are degraded due to the radiation.

Although the two-input NAND circuit NAND1 is used as a two-input logical circuit in the semiconductor integrated circuit 400 in the fourth embodiment, the embodiment is not necessarily limited to the above case. For example, a two-input AND circuit, a two-input OR circuit, a two-input NOR circuit, a two-input XOR circuit, a two-input XNOR circuit, and so on may be used instead. Instead of the two-input NAND circuit NAND1, a three-input NAND circuit, a three-input AND circuit, a three-input OR circuit, a three-input NOR circuit, a three-input XOR circuit, and so on may be used. The MOS transistor PMT2 of the second embodiment may be added to the semiconductor integrated circuit 400 of the fourth embodiment to allow the semiconductor integrated circuit 400 to be set in the enforced high level output mode.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit, comprising:
a signal processing circuit supplied with power from a power source, including a first transistor and a second transistor connected in series, and configured to receive a first input signal at control terminals of the first transistor and the second transistor, and execute signal processing based on the first input signal to output an output signal; and
a third transistor provided between the signal processing circuit and a ground potential and configured to receive a second input signal at a control terminal of the third transistor, the second input signal obtained by level-shifting the first input signal and thereby having a smaller signal amplitude than a signal amplitude of the first input signal, and be turned on or off based on the second input signal.

2. The semiconductor integrated circuit according to claim 1, wherein
the second transistor and the third transistor are each a ring-gate-type MOS transistor.

3. The semiconductor integrated circuit according to claim 1, wherein
the first transistor is a P-channel MOS transistor, and
the second transistor and the third transistor are each an N-channel MOS transistor.

4. The semiconductor integrated circuit according to claim 2, wherein
in the ring-gate-type MOS transistor, a drain layer, a gate, and a source layer are each in ring-shape, a first shallow trench isolation (STI) is provided on an inner peripheral side of the drain layer, the gate is provided on an outer peripheral side of the drain layer, a source layer is provided on an outer peripheral side of the gate, and a second STI is provided on an outer peripheral side of the source layer.

5. The semiconductor integrated circuit according to claim 4, wherein
the first and the second STIs are formed deeper than the drain layer and the source layer.

6. The semiconductor integrated circuit according to claim 1, wherein
an absolute value of a threshold voltage of the third transistor is smaller than absolute values of threshold voltages of the first transistor and the second transistor.

7. The semiconductor integrated circuit according to claim 1, wherein
the first transistor and the second transistor are each a MOS transistor provided on a silicon substrate, and
the third transistor is a MOS transistor provided on an SOI (Silicon on Insulator) substrate.

8. The semiconductor integrated circuit according to claim 7, wherein
a gate insulator film of each of the first transistor and the second transistor is formed of a silicon oxide film, and
a gate insulator film of the third transistor is formed of a composite film including a silicon oxide film and a silicon nitride film.

9. The semiconductor integrated circuit according to claim 1, further comprising:
a fourth transistor, in which one end is connected to the power source, and another end is connected to a portion between the signal processing circuit and the third transistor, the fourth transistor configured to receive, at a control terminal of the fourth transistor, a third input signal having the same signal amplitude as the signal amplitude of the first input signal, be turned on or off based on the third input signal, and forcibly set the output signal in a high level mode.

10. The semiconductor integrated circuit according to claim 9, wherein
the first and the fourth transistors are each a P-channel MOS transistor, and
the second and the third transistors are each an N-channel MOS transistor.

11. The semiconductor integrated circuit according to claim 1, wherein
the signal processing circuit is a driver circuit or an inverter.

12. A semiconductor integrated circuit, comprising:
a two-input logical circuit supplied with power from a power source, including a plurality of transistors, and configured to receive a first input signal and a second input signal which has the same signal amplitude as a signal amplitude of the first input signal, cause the plurality of transistors to turn on or off, and execute logical calculation processing based on the first input signal and the second input signal to output an output signal; and
a first transistor provided between the two-input logical circuit and a ground potential and configured to receive a third input signal at a control terminal of the first transistor, the third input signal having a smaller signal amplitude than the signal amplitudes of the first input signal and the second input signal, and be turned on or off based on the third input signal.

13. The semiconductor integrated circuit according to claim 12, wherein
an absolute value of a threshold voltage of the first transistor is smaller than absolute values of threshold voltages of the plurality of transistors included in the two-input logical circuit.

14. The semiconductor integrated circuit according to claim 12, wherein
the two-input logical circuit is any of a two-input NAND circuit, a two-input AND circuit, a two-input OR circuit, a two-input NOR circuit, a two-input XOR circuit, and a two-input XNOR circuit.
